(19) United States
(12) Patent Application Publication
(10) Pub. No.: US 2026/0242946 A1
(43) Pub. Date: Aug. 20, 2026

(54) SINGLE-CHAMBER ATOMIC LAYER DEPOSITION APPARATUS WITH DUAL-LID CLOSURE SYSTEM

(71) Applicant: SWISS CLUSTER AG, Spiez (CH)

(72) Inventor: Carlos GUERRA, Thun (CH)

(21) Appl. No.: 19/130,927

(22) PCT Filed: Nov. 17, 2022
(86) PCT No.: PCT/EP2022/082235

§ 371 Date: May 16, 2025

(51) Int. Cl. C23C 16/455; C23C 16/44; C23C 16/52

(52) U.S. Cl. CPC C23C 16/45544; C23C 16/4409; C23C 16/4411; C23C 16/4412; C23C 16/52

(57) ABSTRACT

The invention is directed to an atomic layer deposition (ALD) apparatus (1) comprising a monobloc base (2) having a body (21) with a flanged rim (22, 23). It further comprises a dual-lid system (3) with a first lid (31) and a second lid (32), where the latter is at least partly recessed with respect to the former to define an intermediate space (37) in-between. An inner wall of the body delimits an ALD reaction chamber, an opening of which is defined by the flanged rim. The dual-lid system forms a vacuum chamber capping the opening of the reaction chamber of the ALD apparatus. The proposed design circumvents the need for a conventional double-chamber system, which lowers the cost and results in more time-efficient ALD processes. The invention is further directed to a related ALD system.

### BACKGROUND

The invention relates in general to the field of atomic layer deposition (ALD) apparatuses and ALD techniques. In particular, it is directed to a single-chamber ALD apparatus with a dual-lid closure system, where the dual-lid system forms a vacuum chamber capping the opening of the reaction chamber of the ALD apparatus, thereby circumventing the need for a conventional double-chamber system.

ALD is a standard thin-film deposition technique, which can be used to deposit various materials and has a wide range of applications in nanotechnology.

The self-limiting behaviour of precursors involved in ALD processes is key for the sub-nanometre control of the thickness and conformality of the films obtained. Typically, two molecular precursors are sequentially introduced into the ALD reaction chamber (or reactor). For example, use can be made of metal-containing precursor molecules ML_{X}, which comprise a metal element M (e.g., M=Al, Ti, Y, Zr, or Hf) that is bonded to atomic or molecular ligands L.

Such molecules are introduced in the reaction chamber, whereby some (or all) of its ligands react with active surface sites (atomic or molecular ligands at the surface of the substrate), resulting in self-saturating chemisorbed gas molecules (i.e., adsorbates) and volatile by-products. The residual unreacted gas precursor and by-products are evacuated from the reactor during a purging step. These adsorbates and its remaining ligands form a new reactive surface for the subsequent gas precursor to react with. A second molecular gas precursor can then be pulsed into the chamber to react with the remaining ligands of the adsorbates, thereby producing another surface chemistry and further by-products. The latter are evacuated from the reactor during a second purging step, which completes a full ALD cycle. At the end of an ALD cycle, the surface chemistry is reset towards the metal-containing precursor to be pulsed during the following ALD cycle.

An efficient industrial application of ALD requires an apparatus capable of cost-efficiently performing the overall production process (from door to door) as quickly as possible. This includes not only the core ALD process (the coating process), but also all the other steps involved in the production. The overall production process basically includes:
1. Unloading coated parts and loading new parts;
2. Pumping down and heating the reactor chamber. Temperatures of 300° C. and above are commonly used;
3. Bake-out of the parts. This allows the parts to reach the set temperature and further help remove residual moisture and/or other contaminants on the parts. An ozone treatment may possibly be performed to help remove contaminants;
4. The core ALD processes, i.e., coating of the parts with a defined coating thickness (typically varying between a few nanometres to approximately 500 nm), which determines the time duration of the coating process;
5. Cooling down the chamber and parts. This step depends on the desired safety, the actual parts to be coated, and time durations needed to reach an appropriate temperature to remove the coated samples from the reaction chamber without damaging the parts and injuring the operator, or inducing thermal stresses to the coated parts, as these are still warm.

The time duration of each step depends on the size and volume of the reaction chamber, methods used to heat and cool down the reaction chamber, coating process, and surface and geometry of the coated parts. Most, if not all, of the commercially available, large batch ALD reactors, have a conventional double-chamber design. With such a design, the above steps 1, 2, 3, and 5, can add up to more than 12 hours to deposit a few nanometres of thin film on a part.

As the present inventor has realized, considering the different time durations of steps required in a full (i.e., door-to-door) process, the core ALD process itself is not the most time-consuming step. Rather, given the need for shorter overall process times, an efficient optimization should address some or all of the peripheral steps, beyond the core ALD process.

As noted above, conventional ALD systems involve an (inner) reaction chamber, which is placed inside an outer, larger vacuum chamber. This requirement stems from the need to have an inner reaction chamber thoroughly sealed, in order to withstand high temperatures (of 300° C. or more), while the outer chamber can itself be sealed using a special elastomer O-ring, designed for high-temperature applications. Such an O-ring can usually withstand a temperature of approximately 300° C. and is very expensive, especially where large openings need to be sealed. In such double-chamber systems, the inner chamber is sealed with a lid (or door), metal to metal. The outer vacuum chamber is held at a higher pressure than the inner reaction chamber, which ensures a small inward leak rate, preventing gas precursors in the inner chamber to leak into the outer chamber.

In order to heat up the reaction chamber, tubular heaters are typically placed on the larger, outer chamber that surrounds the inner reaction chamber. Thus, the reaction chamber is heated by radiation only, convection is negligible in that case. Now, and as it may be realized, heating through radiation increases significantly the time required to heat the inner chamber walls, the inner chamber atmosphere, and consequently the loaded parts, compared to a conductive heating solution, something that, however, is incompatible with a double-chamber design. I.e., radiative heating takes up several hours in practice. And the same amount of time is required to cool down the chamber to a reasonable temperature, after the coating process.

Moreover, a double-chamber system has additional drawbacks. Inherently, such a design requires an outer chamber to accommodate the inner chamber, which basically doubles the material-related costs and increases the complexity of peripheral devices and systems that require a direct mechanical connection with the inner reaction chamber. Examples of such peripherals include gas inlet/outlet ports, heaters, coolers, and/or metrology sensors (such as pressure gauges and temperature sensors).

The documents US2006196418A1 and U.S. Pat. No. 8,211,235B2 describe an ALD apparatus having a double-chamber system. I.e., the reaction chamber is placed inside a vacuum chamber that completely surrounds the reaction chamber. A reaction chamber lid is provided to close the reaction chamber, while a vacuum chamber lid closes the vacuum chamber. A lifting mechanism makes it possible to access the reaction chamber for loading or unloading parts from the top side of the reaction chamber.

A number of additional patent documents rely on a similar, double-chamber system design, such as US2016281228A1, U.S. Pat. No. 10,273,579B2, US2009263578A1, and U.S. Pat. No. 8,741,062B2. Interestingly, the documents US2009263578A1 and U.S. Pat. No. 8,741,062B2 suggest placing a heater in the vacuum chamber, which further includes an in-feed line for feeding precursor vapour from a precursor source through the vacuum chamber to the reaction chamber. The in-feed line goes through the vacuum chamber wall. In addition, a structure is configured to utilize heat from the reaction chamber heater for preventing condensation of precursor vapour into liquid or solid phase between the precursor source and the sealable reaction chamber.

### SUMMARY

According to a first aspect, the invention is embodied as an atomic layer deposition (ALD) apparatus, which basically includes a monobloc base and a dual-lid system. The base has a body with a flanged rim. The dual-lid system includes a first lid and a second lid, the latter being at least partly recessed with respect to the former to define an intermediate space in-between. An inner wall of the body delimits an ALD reaction chamber, an opening of which is defined by the flanged rim. The body includes at least one port for intake or exhaust of a fluid to or from the ALD reaction chamber. The flanged rim further defines two annular seal surfaces, including a first seal surface nested in a second seal surface. Moreover, peripheral areas of the first lid and the second lid conform to the two annular seal surfaces. This way, the dual-lid system is adapted to close the opening upon pressing said peripheral areas against the two annular seal surfaces to seal the latter, for the dual-lid system to form a vacuum chamber capping the flanged rim.

Instead of completely surrounding the body (delimiting the reaction chamber) of the base, the dual lid system only seals surfaces that laterally delimits the main opening of the reaction chamber. The first lid adequately seals the first seal surface S1, similar to a flanged joint. The intermediate space formed between the lids can be maintained at a slightly larger pressure than the reaction chamber, to mitigate the risk of leaks from the reaction chamber. That is, the dual-lid system forms a vacuum chamber capping the opening of the reaction chamber of the ALD apparatus. In other words, the dual-lid system plays the role of a vacuum chamber, albeit restricted to the sole opening of the reaction chamber, thereby circumventing the need for a conventional double-chamber system, which has several advantages. First, a much smaller locking system is needed, compared to conventional double-chamber designs, resulting in a lighter and less expensive design. All the more, here the reaction chamber can be heated and cooled directly, I.e., by conduction rather than radiation, thanks to the absence of a surrounding chamber, something that drastically reduces the overall process times.

In embodiments, the first lid has a flanged peripheral area, such that the flanged peripheral area of the first lid forms a flanged joint with the first seal surface upon pressing the flanged peripheral area against the first seal surface. A central area of the first lid is inwardly recessed with respect to its flanged peripheral area, so as to expose a concave surface to the reaction chamber. Still, a central area of the second lid is recessed with respect to the central area of the first lid to define said intermediate space in-between.

The concave shape of the first lid makes it possible to avoid angular corners (i.e., sharp edges at the level of the opening), once closed, which makes it possible to improve the distribution of gases in the reaction chamber. Moreover, having a flange joint makes it easier to achieve a zero-clearance assembly as this mitigates stress and buttressing effects when pressing the first lid against the reaction chamber rim.

Preferably, the flanged rim includes a flanged portion that defines the first seal surface. Still, the flanged rim further includes a lip protruding from a periphery of the flanged portion, the lip defining the second seal surface. This way, the first seal surface is recessed from the second seal surface, while the peripheral area of the first lid is correspondingly recessed from a peripheral area of the second lid.

In other words, the lip protrudes from the periphery of the flanged portion. This allows lower temperatures to be achieved at the level of the second seal surface, such that the second seal surface can be sealed using a conventional O-ring, instead of a high-temperature resistant O-ring such as a perfluoroelastomer O-ring, it being noted that perfluoroelastomer O-rings have a limited usability. In addition, the lip allows a smaller dual-lid system to be used (all things being otherwise equal). Plus, the protruding lip can accommodate various features, such as a gas inlet and a gas outlet, and a cooling conduit, as discussed below.

Indeed, in preferred embodiments, the lip of the flanged rim includes a cooling conduit arranged in proximity with, and vis-à-vis, the second seal surface. Plus, the second lid preferably includes a groove extending along its peripheral area, the groove housing an elastomer to seal the second seal surface with the peripheral area of the second lid. More preferably, the elastomer is a fluoroelastomer O-ring.

In embodiments, the ALD apparatus further comprises one or more heat exchangers in mechanical contact with said body, to speed up heat exchanges. The heat exchangers may for instance include one or more resistive heaters. In variants, or in addition, such heat exchangers include one or more cooling conduits, which are preferably coiled, at least partly, around the body. The body may further include one or more temperature sensors, to enable temperature-controlled process.

In embodiments, said at least one port is designed as a flange protruding from the body. Note, the body preferably includes several ports for intake or exhaust of a fluid to or from the ALD reaction chamber. One or more of these ports may for instance be connected to a butterfly valve. Such ports are typically used to introduce gasses into the reaction chamber (e.g., to pulse a precursor into the reaction chamber) and exhaust gases from the reaction chamber, thanks to one or more vacuum pumps (e.g., to purge a precursor out of the reaction chamber). The ports further make it possible to modulate the flows and pressures inside the chamber. For completeness, such ports can be strategically located in accordance with objects to be coated and the intended coating processes.

In preferred embodiments, the dual-lid system further includes a gas inlet designed to allow a gas to be controllably injected in the intermediate space. The dual-lid system further includes a gas outlet designed to allow a gas to be controllably exhausted from the intermediate space. Each of the gas inlet and the gas outlet is preferably provided in a lip protruding from a periphery of a flanged portion of the flanged rim.

In embodiments, the annulus width of the first seal surface is between 1.0 and 5.0 centimetres, preferably between 1.5 and 3.5 centimetres. The annulus width of the second seal surface may for instance be between 0.5 and 4 centimetres, preferably between 1.0 and 3.0 centimetres.

In embodiments, each of the monobloc base, the first lid, and the second lid, includes one of aluminium, stainless steel, and a titanium-based material, and is preferably made of a same material.

According to another aspect, the invention is embodied as an ALD system, wherein the system comprises an ALD apparatus as described above. The ALD apparatus further includes one or more heat exchangers in mechanical contact with the body of the monobloc base of the apparatus.

In preferred embodiments, said body further includes one or more temperature sensors, as well as one or more pressure gauges, if necessary. Plus, the system further comprises one or more temperature-imparting circuits connected to the one or more heat exchangers, as well as a PID temperature controller connected to each of the temperature sensors and the one or more heat exchangers. The one or more heat exchangers may notably include one or more resistive heaters. Moreover, the ALD system may advantageously include a cooling system, e.g., in fluid communication with one or more of the heat exchangers. Optionally, another cooling system is set in fluid communication with a cooling conduit arranged in the lip of the flanged rim, in proximity with, and vis-à-vis, the second seal surface.

In preferred embodiments, the body includes several ports for intake or exhaust of a fluid to or from the ALD reaction chamber. There, the ALD system may further include a gas delivery system in fluid connection with one or more of the several ports. In variants, or in addition, the ALD system may advantageously include an exhaust system in fluid connection with one or more of the several ports, as well as, e.g., one or more vacuum pumps in fluid connection with the exhaust system. The ALD system may also include pressure control means configured to adjust a gas pressure inside the intermediate space of the dual-lid system.

### BRIEF DESCRIPTION OF THE DRAWINGS

These and other objects, features and advantages of the present invention will become apparent from the following detailed description of illustrative embodiments thereof, which is to be read in connection with the accompanying drawings. The illustrations are for clarity in facilitating one skilled in the art in understanding the invention in conjunction with the detailed description. In the drawings:

FIG. 1 is a 3D view of an atomic layer deposition (ALD) apparatus, according to embodiments. The ALD apparatus is shown in an open configuration, i.e., a configuration in which the dual-lid system does not seal the opening of the ALD reaction chamber;

FIG. 2 shows a cutaway of the ALD apparatus of FIG. 1 (using a simplified 3D view thereof), in a closed configuration, as in embodiments. I.e., the dual-lid system seals the opening of the ALD reaction chamber. The inset depicts a full 3D view, albeit simplified with respect to the view of FIG. 1, further showing the cutting plane P used to for the cutaway;

FIGS. 3A-3D shows various views of the ALD apparatus (simplified views) of FIG. 2, respectively corresponding to: a top view (FIG. 3A), a side view (FIG. 3B), a rear view (FIG. 3C), and a front view (FIG. 3D);

FIGS. 4A and 4B are simplified cross-sectional views of the ALD apparatus of FIG. 2, viewed from the side. The views show the ALD apparatus in an open configuration (FIG. 4A) and in a closed configuration (FIG. 4B);

FIGS. 5A and 5B are simplified cross-sectional views of a variant to the ALD apparatus of FIG. 2, viewed from the side, where the flanged rim does not include a peripheral lip protruding from the flanged portion, contrary to the designs assumed in FIGS. 1-4B. FIGS. 5A and 5B respectively show the apparatus in open and closed configurations; and

FIG. 6 is a block diagram schematically illustrating selected components of an ALD system including an ALD apparatus such as shown in FIGS. 1-5B, according to embodiments.

The accompanying drawings show simplified representations of ALD apparatuses or parts thereof, as involved in embodiments. Technical features depicted in the drawings are not necessarily to scale. Similar or functionally similar elements in the figures have been allocated the same numeral references, unless otherwise indicated. Numeral references pertain to a system, apparatuses, and parts thereof, as involved in embodiments of the present invention.

ALD apparatuses and systems embodying the present invention will now be described, by way of non-limiting examples.

### DETAILED DESCRIPTION OF EMBODIMENTS OF THE INVENTION

The following description is structured as follows. General embodiments and high-level variants are described in section 1. Section 2 addresses particularly preferred embodiments.

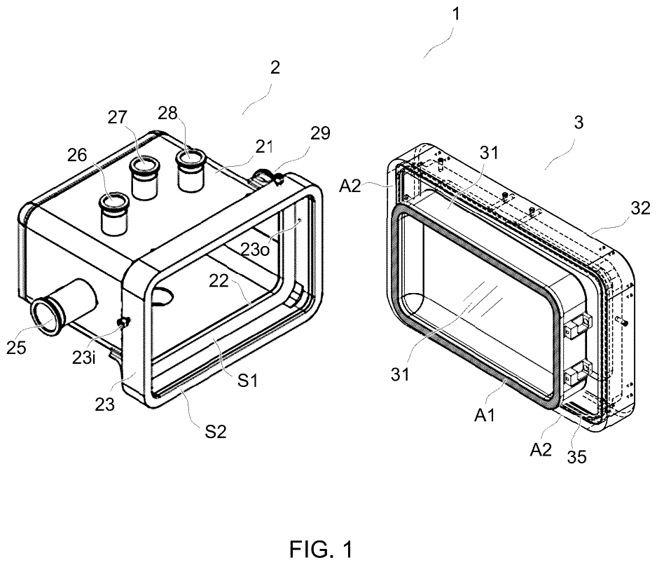

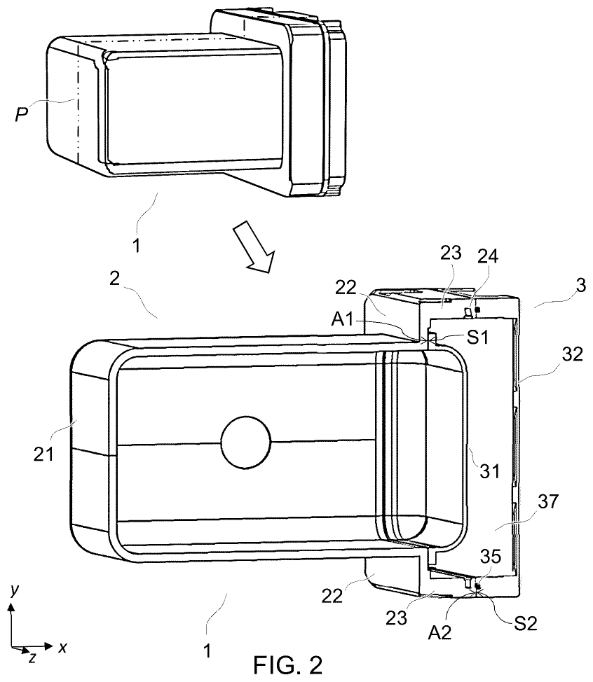

A first aspect of the invention is now described in detail, in reference to FIGS. 1 and 2. This aspect concerns an atomic layer deposition (ALD) apparatus 1. The ALD apparatus basically includes a base 2 and a dual-lid system 3.

The base is made of a single block. I.e., it is a monobloc container, which is open on one side (at least). The base 2 is typically made of metal or a metal alloy, as assumed in the following. The base 2 includes a body 21 culminating in a flanged rim 22, 23. The inner wall of the body 21 delimits (i.e., bounds) the reaction chamber of the ALD apparatus. A main opening of the reaction chamber is defined by the flanged rim 22, 23.

In detail, the flanged rim 22, 23 forms a flange with a radially projecting collar (i.e., a flat rim). This collar is an annular, ring-like portion projecting outwardly and radially from the main axis of the body 21 at the level of its peripheral rim. Note, the flange may actually have various shapes, such that the opening may have various shapes too, e.g., circular, oblong, or polygonal. The average diameter of the opening is typically between 0.5 and 1.5 m. The chamber itself can be cylindrical, cubical, or parallelepipedal, although it is preferably generally convex, with rounded edges and corners, to avoid spurious effects with gas mixtures in the chamber. The body 21 further includes one or more ports 25-29 for intake or exhaust of fluids (usually gases) to or from the ALD reaction chamber.

As its name suggests, the dual-lid system 3 includes two lids 31, 32, i.e., a first lid 31 and a second lid 32. The second lid 32 is at least partly recessed with respect to the first lid 31. That is, a substantial area (typically the central area) of the second lid 32 is recessed with respect to the first lid (or a substantial area thereof). This defines an intermediate space 37, which is delimited by the two lids 31, 32. This intermediate space 37 forms a compact vacuum chamber, see FIGS. 1, 2, 4A-5B. The dual-lid system 3 is meant to close the opening of the reaction chamber.

As seen in FIGS. 1, 2, and 4A to 5B, the flanged rim 22, 23 defines two annular seal surfaces S1, S2, namely a first seal surface S1 and a second seal surface S2. The first seal surface S1 is nested in the second seal surface S2, as explained in further detail below. Peripheral areas A1, A2 are correspondingly formed on the first lid 31 and the second lid 32. The peripheral areas A1, A2 of the lids 31, 32 are designed so as to conform to the two annular seal surfaces S1, S2. I.e., the peripheral areas A1, A2 are shaped in accordance with the two annular seal surfaces S1, S2, so as to tightly seal the latter upon closing the opening of the reaction chamber with the dual-lid system 3, i.e., upon pressing the peripheral areas A1, A2 of the dual-lid system against the respective annular seal surfaces S1, S2. Thanks to these conformal surfaces, the dual-lid system 3 can suitably close and seal the opening of the reaction chamber. Once closed, the dual-lid system 3 forms a vacuum chamber, which caps the flanged rim 22, 23.

Comments are in order. The two annular seal surfaces S1, S2 are defined by the flanged rim 22, 23, opposite to the body, i.e., on the other side of the body 21 with respect to the flat rim. The second seal surface S2 is outside the first seal surface S1, i.e., farther out, much like concentric annuli. However, the two annular surfaces need not extend in a same plane, as illustrated in embodiments discussed below in detail. Still, the first seal surface S1 can be regarded as being nested in the second seal surface S2, because the projection of the latter surround the former in the extension plane of the first surface S1. So, the first surface S1 is inside the second surface, at least in projection.

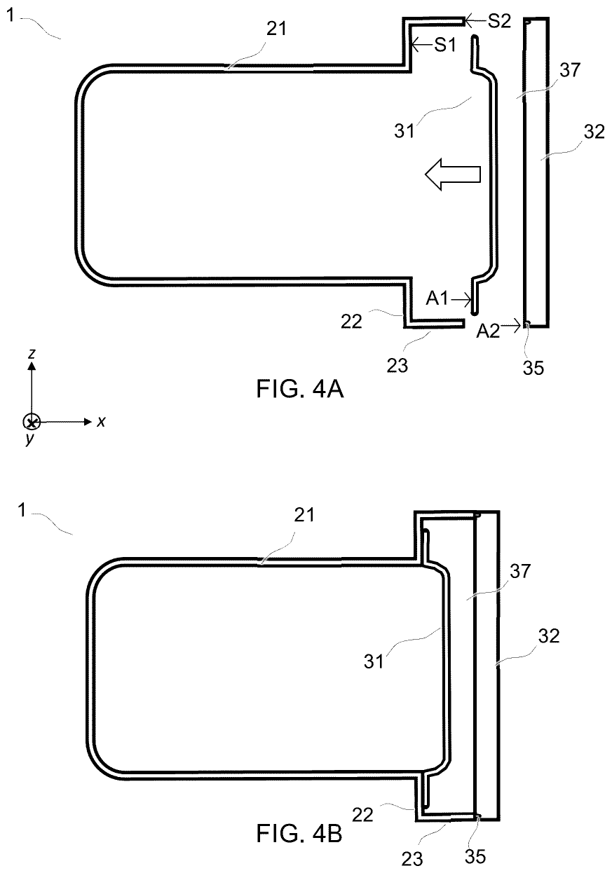

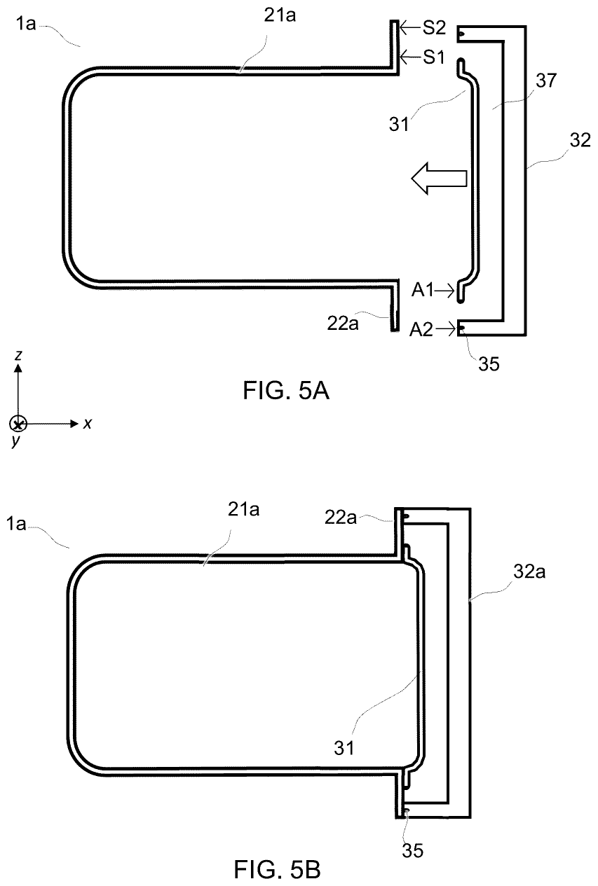

Similarly, the peripheral areas A1, A2 of the lids need not be defined in a same plane, although they can be (compare FIGS. 4A, 4B with FIGS. 5A, 5B). The dual-lid system is meant to cap the flanged rim 22, 23. That is, in the closed position, the dual-lid system caps the sole opening of the reaction chamber. In other words, instead of completely surrounding the body 21 (reaction chamber) of the base 2, the dual lid system 3 only seals surfaces that laterally delimits the main opening of the reaction chamber. This has several advantages that are discussed later in detail.

Note, contrary to the depiction in FIG. 1, the present ALD apparatuses may possibly include two main openings, e.g., on opposite sides of the body 21. The second opening may similarly be defined by a second flanged rim. In that case, the apparatus includes two dual-lid systems 3 such as described above, each meant to cap respective openings, as defined by the respective flanged rims. However, a single opening and a single dual-lid system will normally be sufficient in practice, as assumed in the following. In principle, the parts to be coated may be loaded/unloaded from any side of the reaction chamber. However, in practice, this opening is normally situated in the front of the chamber, once the ALD apparatus 1 is installed, e.g., in a clean room facility. In operation, the parts to be coated can be loaded using a dedicated frame, which may possibly be designed to hold different types of substrates. For instance, this frame may contain customized, perforated plates, or blind plates, to improve the homogenous distribution of the gas precursors when pulsing the precursors or purging out the precursors.

The dual-lid system 3 can be regarded as a safe space, which will advantageously be pressure-controlled. I.e., in operation, the intermediate space 37 formed between the lids is typically at a slightly larger pressure than the reaction chamber, to mitigate the risk of leaks from the reaction chamber. To that aim, the dual-lid system may advantageously accommodate an independent gas flow inlet 23i and preferably a separate outlet 230 too (see FIG. 1), in order to fill it with an inert gas (e.g., N2 or Ar) and control the pressure inside the vacuum chamber of the dual-lid system 3. So, the vacuum chamber defined by the dual-lid system may be connected to a gas pressure circuit, allowing to increase and modulate the pressure in this space, and also vent this space.

As discussed above, the opening of the reaction chamber can be closed and sealed by the dual-lid system 3, by pressing the peripheral areas A1, A2 of the lids 31, 32 against their respective annular surfaces S1, S2. Assuming that the first lid 31 has a metal peripheral area A1, this results in forming a metal-to-metal seal (or joint) between the first lid 31 and the first seal surface S1, similar to a flanged joint. Preferably, the first lid 31 is made entirely of metal. In variants, it is made of a metal alloy, resulting in a similar type of seal. Similarly, the second lid 32 can be entirely made of metal or a metal alloy. Examples of suitable materials for the body and the dual-lid system include titanium-based materials, stainless steel, and aluminium-based alloys. The body of the chamber and the first lid may for instance be made of a same, high-performance material, while the second lid can possibly be made of less performant, and therefore cheaper, material, such as aluminium. As further seen in FIG. 1, the second lid 32 typically includes an elastomer O-ring 35 to seal the second seal surface S2.

Importantly, in the present context, both the seal surfaces S1 and S2 are defined by the flanged rim 22, 23 of the body 21 of the reaction chamber itself, contrary to prior art solutions where one or each of the seal surfaces are defined on an outer vacuum chamber that completely surrounds the inner reaction chamber. In other words, the dual-lid system plays the role of a vacuum chamber, albeit restricted to the sole opening of the reaction chamber. Thus, the dual-lid system does not need to completely surround the vacuum chamber. Rather, the dual-lid system dimensions are typically commensurate with the reaction chamber opening's, as illustrated in the accompanying drawings.

The central area of the second lid 32 is typically recessed from the first lid 31 by a few centimetres. That said, the volume of the space defined in the dual-lid system is not critical as long as this space can be pressurized to ensure a suitable pressure gradient. ALD processes typically operate under primary vacuum, i.e., in a pressure range going from 10⁻¹ to 5 mbar, while the intermediate space is at a slightly higher pressure, typically 1 mbar or more (e.g., between 2 and 10 mbar above the pressure in the vacuum chamber).

To summarize, in the proposed ALD apparatus, the ALD reaction chamber is closed by a dual-lid system 3 that only seals and caps a main opening of the reaction chamber. That is, the dual-lid system forms a compact intermediate space 37, which only caps the flanged rim and, thus, the main opening of the reaction chamber. Remarkably, this solution circumvents the need for a conventional double chamber, i.e., where the vacuum chamber completely surrounds the inner reaction chamber. On the contrary, here a much smaller intermediate space and, thus, a much smaller locking system 3 is needed. This intermediate space, albeit reduced, is still necessary to have the main reaction chamber sealed by way of an efficient seal such as a metal-to-metal seal. This, in turn, allows a medium vacuum to be achieved in the intermediate space 35 and makes it possible to heat the chamber to temperatures higher than 300° C., for which a conventional elastomer O-ring seal is not possible. Moreover, here the reaction chamber can be heated and cooled directly by conduction rather than radiation, thanks to the absence of a surrounding chamber, something that drastically reduces the overall process times.

All this is now described in detail, in reference to particular embodiments of the invention. To start with, the first lid 31 preferably has a flanged peripheral area A1, as assumed in the accompanying drawings and best seen in FIGS. 4A-5B. The flanged peripheral area A1 of the first lid 31 forms a flanged joint with the first seal surface S1 upon pressing the flanged peripheral area A1 against the first seal surface S1. Meanwhile, the central area of first lid 31 exposes a concave surface to the reaction chamber. I.e., the central area of first lid 31 is inwardly recessed with respect to its flanged peripheral area, so as to bulge out from the reaction chamber. Still, the central area of the second lid 32 is nevertheless recessed with respect to the central area of first lid 31, so as to maintain an intermediate space 37 in-between. The concave shape of the first lid 31 makes it possible to avoid angular corners (i.e., sharp edges at the level of the opening), once closed. This, in operation, makes it possible to improve the distribution of gases in the reaction chamber. The latter may similarly have a recessed rear part (preferably rounded), hence resulting in a more symmetric inner space in the reaction chamber. I.e., the reaction chamber can advantageously have a generally convex shape, to improve the distribution of gases in the chamber. Moreover, having a flange joint makes it easier to achieve a zero-clearance assembly as this mitigates stress and buttressing effects when pressing the first lid 31 against the reaction chamber rim.

Referring more particularly to FIGS. 1, 2, 4A and 4B, the flanged rim 22, 23 preferably has a flanged portion 22, which defines the first seal surface S1. As best seen in FIGS. 4A, 4B, a peripheral lip 23 protrudes from the periphery of the flanged portion 22. This lip 23 actually defines the second seal surface S2. As a result of this geometry, the first seal surface S1 is recessed from the second seal surface S2, while the peripheral area A1 of the first lid 31 is correspondingly recessed from the peripheral area A2 of the second lid 32.

In other words, the lip 23 protrudes from the periphery of the flanged portion 22. This allows lower temperatures to be achieved at the level of the second seal surface S2. That is, in operation, the temperature in the reaction chamber walls 21 and the seal surface S1 will typically be set to, e.g., 300 to 400° C. However, due to natural (or forced) temperature gradients along the lip extension 23, the seal surface S2 will typically be at a temperature lower than 200° C. This, in turn, makes it possible to avoid the use of a high-temperature resistant O-ring, such as a perfluoroelastomer O-ring (e.g., so-called FFKM or FFPM O-rings). Instead, a mere fluoroelastomer O-ring (e.g., FPM, FKM O-ring) can be used to seal the surface S2, which allows a more cost-effective solution. Not only the perfluoroelastomer O-rings are expensive, but, in addition, they have a limited usability. I.e., such rings are typically useless after a few uses at high temperatures.

In more detail, the second lid 32 may include a groove extending along its peripheral area A2. So, this groove can house an elastomer 35 to seal the second seal surface S2 with the peripheral area A2 of the second lid 32. While the reaction chamber is preferably sealed metal-to-metal by the first seal, the second lid 32 can be suitably sealed with an elastomer such as an FKM O-ring, assuming the temperature of the second seal surface does not exceed 200° C. Else a more sophisticated O-ring (e.g., FFKM, FFPM) must be used, as noted above.

The protruding lip 23 seen in FIGS. 1, 2, 4A, 4B, is optional. Other designs can be contemplated, which merely have a flat rim, without any protruding lip, as assumed in FIGS. 5A and 5B. In these examples, the lack of lip extension 23 typically causes the second seal surface S2 to be at a temperature that is closer to the temperature of the first seal surface S1, which solution may require a perfluoroelastomer O-ring. The apparatus 1a is otherwise very similar, showing a body 21a culminating in the flanged rim 22a. An alternative, however, is to make that flange portion (flat rim 22a) sufficiently wide, laterally. The corresponding peripheral area A2 would accordingly have a larger diameter, allowing a sufficient temperature gradient to be achieved, so that the perfluoroelastomer O-ring can be replaced by a fluoroelastomer O-ring.

Still, the design proposed in FIGS. 1, 2, 4A, and 4B, is preferred, if only because this permits a smaller dual-lid system to be used (all things being otherwise equal). Plus, the protruding lip 23 has additional advantages. In particular, a gas inlet 23i and a gas outlet 230 may be formed in the protruding lip 23. As evoked earlier, the gas inlet 23i and the gas outlet 230 allow a gas to be controllably injected in and exhausted from the intermediate space 37, to maintain a slight overpressure in the intermediate space 37.

Moreover, the protruding lip 23 may accommodate a cooling conduit 24, as best seen in FIG. 2. That is, the lip 23 of the flanged rim 22, 23 may advantageously include a cooling conduit 24 arranged in proximity with, and vis-à-vis, the second seal surface S2. I.e., the conduit is provided in the lip 23, in the vicinity of the surface S2, so as to allow the seal surface S2 to be cooled down, if needed. In operation, this conduit 24 can be connected to a cooling circuit, whereby a coolant can be circulated through the conduit 24. The cooling conduit 24 makes it easier to reach temperatures lower than 200° C. in the vicinity of the surface S2, to avoid the use of an expensive O-ring, while the chamber walls and the seal surface S1 can be maintained at temperatures above 300° C.

Notwithstanding the cooling conduit 24, meant to cool down the periphery of the second lid area A2, the first lid 31 can typically be heated thanks to heating elements in thermal contact therewith, similar to the body 21, to help maintain a uniform process temperature across the whole reaction chamber. On the contrary, the second lid 32 is not heated, so that its inner area can remain at a much lower temperature, close to the ambient temperature. Typically, a large portion of the second lid 32 remains at a temperature less than 60° C. All in all, the design proposed in FIGS. 1, 2, 4A-4B makes it easier to maintain the periphery of the second lid 32 (including the peripheral area A2 housing the O-ring 35) at a temperature that is less than 200° C., such that a conventional O-ring can be used.

The apparent dimensions of the various parts and components of the ALD apparatus 1 are not necessarily to scale in the accompanying drawings. While the 3D views shown in FIGS. 1, 2 are meant to be realistic, the schematic cross-sections seen in FIGS. 4A-5B are not. To fix ideas, the annulus width of the first seal surface S1 is preferably between 1.0 and 5.0 centimetres, more preferably between 1.5 and 3.5 centimetres. This annulus width corresponds to the differences between the outer radius and the inner radius of the annular seal surface S1, assuming the latter is designed as a perfect annulus. However, the seal surface does not need to be circular; it can for example be oblong or polygonal, as noted earlier. The larger the sealing area the better the seal, in principle. However, a too large seal area may also give rise to clearance issues. A satisfactory trade-off is already achieved with widths between 1.0 and 5 centimetres, though best results can, in principle, be achieved with a width between 1.5 and 3.5 centimetres. Conversely, the width of the second surface is typically smaller than that of the first seal surface S1. I.e., the annulus width of the second seal surface S2 is preferably between 0.5 and 4 centimetres, and more preferably between 1.0 and 3.0 centimetres.

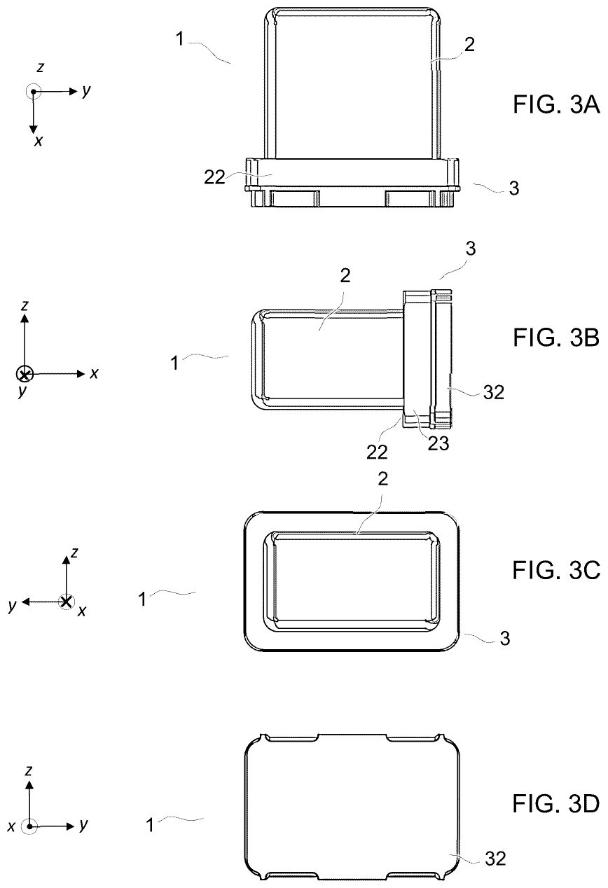

In the example of FIG. 1, five ports 25, 26, 27, 28, 29 are provided, which are arranged on the body 21 of the base 2. Note, some of the ports 25-29 can be designed to cooperate with respective valves. E.g., an exhaust port used to modulate the pressure inside the reaction chamber can typically be connected to a vacuum pump via a butterfly valve. For the rest, the ports are typically flanged, as assumed in FIG. 1, to enable flanged joints. At least two ports are usually needed, to which multiple gas sources can be connected, to allow intake/exhaust of multiple gases. Note, however, that the port number can be reduced, possibly down to a single port, if multiple tubes branch into that single port. Note, the ports 25-29 must be distinguished from the main opening of the reaction chamber, which is normally much larger than the ports. The ports 25-29 are not shown in FIGS. 2-5B, for the sake of simplifying depictions.

Thanks to the ports, the apparatus 1 can be connected to a gas delivery system for directly feeding precursor vapours from precursor sources into the reaction chamber. Some of the ports can also be used to remove vapours to an exhaust assembly, thanks to one or more vacuum pumps, during the ALD process. In addition, some of the ports can be used to control pulsing and purge steps during the coating process. To summarize, the ports 25-29 can be used to introduce gas precursors and/or carrier gas into the chamber and exhaust such gases to one or more vacuum pumps, while modulating the flows and pressures inside the reaction chamber. In particular, one may want to adequately position these ports 25-29 in accordance with objects to be coated and the intended coating processes, e.g., to optimize the process times and film uniformity on different geometrical substrates or objects to be coated.

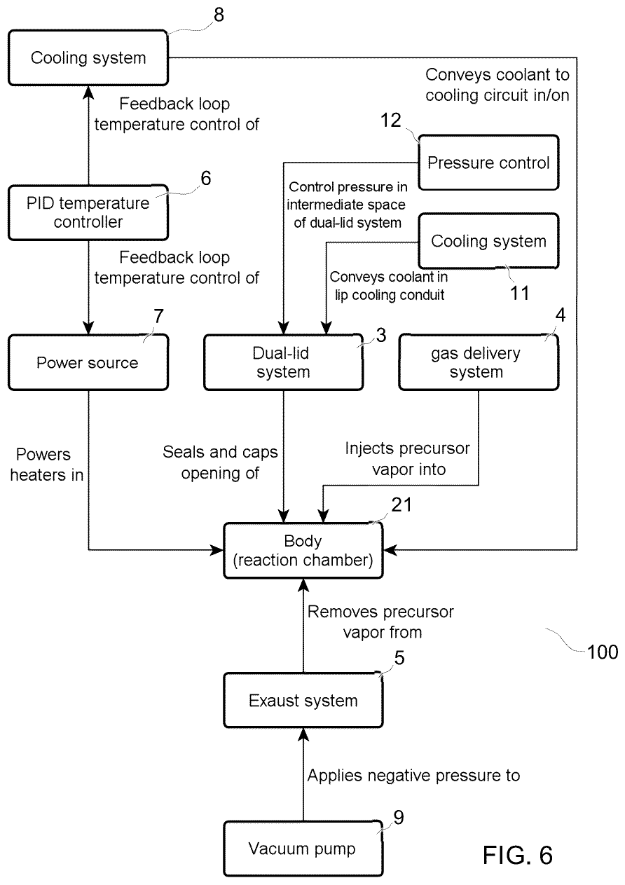

The present ALD apparatuses may include a number of additional features, which are not necessarily depicted in the accompanying drawings, for the sake of conciseness. In particular, the body 21 may include one or more temperature sensors, for reasons explained later. Moreover, the ALD apparatus 1 may further comprise one or more heat exchangers in mechanical contact with the body 21 of the base 2, as indicated in the diagram of FIG. 6. As explained above, such heat exchangers make it possible to directly heat or cool the reaction chamber, by conduction. The heat exchangers may notably include resistive heaters, connected to one or more power sources, to controllably heat the reaction chamber. In addition, some of the heat exchangers may include one or more cooling conduits, which are preferably coiled, at least partly, around the body 21 of the base 2. This way, the reaction chamber can be forced cooled, by conduction, to reduce the overall process time compared with conventional double-chamber solutions.

Referring now to FIG. 6, another aspect of the invention is now described, which concerns an ALD system 100. The system 100 revolves around an ALD apparatus 1 as described above, and further include one or more peripheral systems or components meant to cooperate with the ALD apparatus 1, with a view to performing ALD processes.

The apparatus 1 may notably include one or more heat exchangers that are arranged in mechanical contact with the body 21 of the base 2 of the apparatus 1. In addition, the ALD apparatus 1 may include further heat exchangers in mechanical contact with one or each of the lids 31, 32, for reasons explained earlier. Moreover, the body 21 of the ALD apparatus may include one or more temperature sensors, to allow temperature-controlled processes. To that aim, the system 1 may further comprise one or more temperature-imparting circuits, which are connected to the one or more heat exchangers (as described earlier). Plus, the system 100 may advantageously include a PID temperature controller 6, which is connected to each of the temperature sensors and the one or more heat exchangers. PID stands for “Proportional, Integral and Derivative”. The PID controller 6 enables a control loop mechanism, which use feedback signals from the temperature sensors to allow a continuously modulated temperature control, via the heat exchangers.

The PID controller may notably be connected to one or more power sources 7 (themselves connected to resistive heaters) and/or a cooling system 8. That is, the heat exchangers may include resistive heaters and the corresponding temperature-imparting circuits may include one or more power sources, which are connected to the resistive heaters. In addition, the ALD system 100 may include a cooling system 8, which is in fluid communication with one or more of the heat exchangers.

Note, the ALD system 100 may include a further cooling system 11, in fluid communication with a cooling conduit 24 arranged in the protruding lip 23 of the flanged rim 22, 23 (i.e., in proximity with, and vis-à-vis, the second seal surface S2), as described earlier. This way, the surface of the door flange can be cooled in order to avoid the use of expensive FFKM O-rings. That is, the system 100 may possibly include distinct cooling systems 9, 11, enabling distinct cooling circuits, as assumed in the diagram of FIG. 6. One of the cooling systems 9 is in fluid communication with heat exchangers on the body of the monobloc base 2, while the other 11 is in fluid communication with the cooling conduit 24.

In embodiments, the ALD system 100 further includes a gas delivery system 4, where the system 4 is in fluid connection with one or more of the ports 25-29 of the ALD apparatus 1. This gas delivery system 4 may notably be used to feed precursor vapour from a precursor source into the reaction chamber of the ALD apparatus 1. In variants, or in addition, the ALD system 100 includes an exhaust system 5 in fluid connection with one or more of the ports 25-29. One or more vacuum pumps 9 may for instance be set in fluid connection with the exhaust system, to exhaust gases from the reaction chamber of the ALD apparatus 1, in operation. Species can thus be removed, during the ALD process, from the reaction chamber via one or more outlets, and conveyed to an exhaust assembly, itself connected to one or more vacuum pumps.

In embodiments, the ALD system 100 further includes pressure control means 12, which are configured to adjust a gas pressure inside the intermediate space of the dual-lid system 3. As explained earlier, the dual-lid system 3 may include a gas inlet 23i and a gas outlet 230, which are preferably provided in the lip 23 protruding from the flanged portion 22 of the flanged rim 22, 23. Thus, a gas circuit can be connected to each of the inlet 23i and the outlet 230 to controllably adjust the pressure inside the intermediate space 37 of the dual-lid system 3, thanks to the pressure control means 12. Now, such pressure control means 12 may possibly be connected to the vacuum pump 9. That is, the outlet 230 may be connected to the vacuum pump 9, via an on/off (i.e., open/close) valve. So, the pressure inside the intermediate space 37 can simply be modulated by introducing gas into this space 37, while opening or closing this valve. For completeness, the ALD system 100 is preferably controlled via a programmable logic controller (PLC) or a controller for process automation.

While the present invention has been described with reference to a limited number of embodiments, variants, and the accompanying drawings, it will be understood by those skilled in the art that various changes may be made, and equivalents may be substituted without departing from the scope of the present invention. In particular, a feature (device-like or method-like) recited in a given embodiment, variant or shown in a drawing may be combined with or replace another feature in another embodiment, variant or drawing, without departing from the scope of the present invention. Various combinations of the features described in respect of any of the above embodiments or variants may accordingly be contemplated, that remain within the scope of the appended claims. In addition, many minor modifications may be made to adapt a particular situation or material to the teachings of the present invention without departing from its scope. Therefore, it is intended that the present invention is not limited to the particular embodiments disclosed, but that the present invention will include all embodiments falling within the scope of the appended claims. In addition, many other variants than explicitly touched above can be contemplated. For example, other materials than those explicitly mentioned may be relied on. In addition, the ALD apparatus 1 may have a different structural aspect, e.g., with a different arrangement of the ports 25-29 or the main opening of the reaction chamber.

REFERENCE LIST

| | |
|---|---|
| 1 | ALD apparatus |
| 2 | ALD base |
| 3 | Dual-lid system |
| 4 | Gas delivery system |
| 5 | An exhaust system |
| 6 | PID temperature controller |
| 8 | Main cooling system |
| 9 | Vacuum pumps |
| 11 | Peripheral cooling system |
| 12 | Pressure control means |
| 21 | Base body |
| 22 | Flanged portion |
| 23 | Protruding lip |
| 24 | Cooling conduit |
| 31 | First lid |
| 32 | Second lid |
| 35 | Elastomer |
| 37 | Intermediate space |
| 100 | ALD system |
| 22, 23 | Flanged rim |
| 22a | Flange portion (flat rim) |
| 23i | Gas inlet |
| 23o | Gas outlet |
| 25-29 | Ports |
| A1, A2 | Lid peripheral areas |
| A1 | First lid peripheral area |
| A2 | Second lid peripheral area |
| S1 | First seal surface |
| S1, S2 | Annular seal surfaces |
| S2 | Second seal surface |

1. An atomic layer deposition apparatus, or ALD apparatus, comprising:
a monobloc base having a body with a flanged rim; and
a dual-lid system including a first lid and a second lid, the latter being at least partly recessed with respect to the former to define an intermediate space in-between, wherein
an inner wall of the body delimits an ALD reaction chamber, an opening of which is defined by the flanged rim,
the body includes at least one port for intake or exhaust of a fluid to or from the ALD reaction chamber,
the flanged rim defines two annular seal surfaces, including a first seal surface nested in a second seal surface, and
peripheral areas of the first lid and the second lid conform to the two annular seal surfaces, whereby the dual-lid system is adapted to close the opening upon pressing said peripheral areas against the two annular seal surfaces to seal the latter, for the dual-lid system to form a vacuum chamber capping the flanged rim.

2. The ALD apparatus according to claim 1, wherein the first lid has a flanged peripheral area, such that the flanged peripheral area of the first lid forms a flanged joint with the first seal surface upon pressing the flanged peripheral area against the first seal surface, while a central area of the first lid is inwardly recessed with respect to its flanged peripheral area, so as to expose a concave surface to the reaction chamber, and a central area of the second lid is recessed with respect to the central area of the first lid to define said intermediate space in-between.

3. The ALD apparatus according to claim 1, wherein
the flanged rim includes:
a flanged portion that defines the first seal surface;
a lip protruding from a periphery of the flanged portion, the lip defining the second seal surface, whereby the first seal surface is recessed from the second seal surface, the peripheral area of the first lid being correspondingly recessed from the peripheral area of the second lid.

4. The ALD apparatus according to claim 3, wherein
the lip of the flanged rim includes a cooling conduit arranged in proximity with, and vis-à-vis, the second seal surface.

5. The ALD apparatus according to claim 1, wherein
the second lid includes a groove extending along its peripheral area, the groove housing an elastomer to seal the second seal surface with the peripheral area of the second lid.

6. The ALD apparatus according to claim 1, wherein the ALD apparatus further comprises one or more heat exchangers in mechanical contact with said body.

7. The ALD apparatus according to claim 6, wherein
the heat exchangers include one or more resistive heaters.

8. The ALD apparatus according to claim 6, wherein
the heat exchangers include one or more cooling conduits.

9. The ALD apparatus according to claim 6, wherein
the body further includes one or more temperature sensors.

10. The ALD apparatus according to claim 1, wherein
each of said at least one port is designed as a flange protruding from the body.

11. The ALD apparatus according to claim 1, wherein
the dual-lid system further includes a gas inlet designed to allow a gas to be controllably injected in the intermediate space, and
the dual-lid system further includes a gas outlet designed to allow a gas to be controllably exhausted from the intermediate space.

12. The ALD apparatus according to claim 1, wherein
an annulus width of the first seal surface is between 1.0 and 5.0 centimetres.

13. The ALD apparatus according to claim 1, wherein
an annulus width of the second seal surface is between 0.5 and 4 centimetres.

14. The ALD apparatus according to claim 1, wherein
each of the monobloc base, the first lid, and the second lid, includes one of aluminium, stainless steel, and a titanium-based material.

15. An atomic layer deposition system, or ALD system, wherein the system comprises
an ALD apparatus, comprising:
a monobloc base having a body with a flanged rim;
a dual-lid system including a first lid and a second lid, the latter being at least partly recessed with respect to the former to define an intermediate space in-between; and
the ALD apparatus further includes one or more heat exchangers in mechanical contact with said body,
wherein
an inner wall of the body delimits an ALD reaction chamber, an opening of which is defined by the flanged rim,
the body includes at least one port for intake or exhaust of a fluid to or from the ALD reaction chamber,
the flanged rim defines two annular seal surfaces, including a first seal surface nested in a second seal surface, and
peripheral areas of the first lid and the second lid conform to the two annular seal surfaces, whereby the dual-lid system is adapted to close the opening upon pressing said peripheral areas against the two annular seal surfaces to seal the latter, for the dual-lid system to form a vacuum chamber capping the flanged rim.

16. The ALD system according to claim Error! Reference source not found., wherein
said body further includes one or more temperature sensors, and
the system further comprises
one or more temperature-imparting circuits connected to the one or more heat exchangers, and
a PID temperature controller connected to each of the temperature sensors and the one or more heat exchangers.

17.-18. (canceled)

19. The ALD system according to claim Error! Reference source not found., wherein
the ALD system further includes a cooling system in fluid communication with a cooling conduit arranged in the lip of the flanged rim, in proximity with, and vis-à-vis, the second seal surface.

20. The ALD system according to claim Error! Reference source not found., wherein
the body includes several ports for intake or exhaust of a fluid to or from the ALD reaction chamber, and
the ALD system further includes a gas delivery system in fluid connection with one or more of the several ports.

21. The ALD system according to claim Error! Reference source not found., wherein
the body includes several ports for intake or exhaust of a fluid to or from the ALD reaction chamber, and
the ALD system further includes
an exhaust system in fluid connection with one or more of the several ports.

22. The ALD system according to claim Error! Reference source not found., wherein the ALD system further includes pressure control means configured to adjust a gas pressure inside the intermediate space of the dual-lid system.
